(19) United States
(12) Patent Application Publication
(10) Pub. No.: US 2024/0030249 A1
(43) Pub. Date: Jan. 25, 2024

(54) SOLID-STATE IMAGING ELEMENT AND ELECTRONIC DEVICE

(71) Applicant: SONY SEMICONDUCTOR SOLUTIONS CORPORATION, Kanagawa (JP)

(72) Inventor: Kazuki YOSHIDA, Kumamoto (JP)

(73) Assignee: SONY SEMICONDUCTOR SOLUTIONS CORPORATION, Kanagawa (JP)

(21) Appl. No.: 18/254,222

(22) PCT Filed: Nov. 17, 2021
(86) PCT No.: PCT/JP2021/042247

§ 371 Date: May 24, 2023

(30) Foreign Application Priority Data
Dec. 4, 2020 (JP) 2020-202142

(51) Int. Cl. H01L 27/146

(52) U.S. Cl. CPC H01L 27/14621; H01L 27/14627; H01L 27/14623

(57) ABSTRACT

Provided are a solid-state imaging element and an electronic device capable of suppressing a decrease in sensitivity even if a partition wall is provided between color filters for each pixel. A solid-state imaging element includes a plurality of pixels. Each of the plurality of pixels includes a first lens that condenses incident light, a color filter that absorbs light having transmitted through the first lens and having a specific wavelength, the color filter having different wavelength characteristics of light absorption between an outer peripheral part and an inner region of the outer peripheral part, and a photoelectric conversion unit that photoelectrically converts the incident light having transmitted through the color filter, and the inner region is formed according to a light condensing region of the incident light in the color filter.

### TECHNICAL FIELD

The present disclosure relates to a solid-state imaging element and an electronic device.

### BACKGROUND ART

In an electronic device capable of capturing a color image, incident light enters a light receiving surface of a photoelectric conversion element via a color filter. The Light having obliquely entered the light receiving surface may cross the boundary of the color filter, and enter another color filter adjacent thereto. Accordingly, crosstalk (color mixture) due to entrance of the light into a photoelectric conversion element corresponding to the another color filter might occur.

For this reason, a technique of providing a partition wall between the color filters for each pixel to suppress crosstalk has been known. However, traveling of the incident light is suppressed by the partition wall, and there is a possibility that the sensitivity of the photoelectric conversion element is lowered.

### CITATION LIST

### Patent Document

Patent Document 1: Japanese Patent Application Laid-Open No. 2018-182397
Patent Document 2: Japanese Patent Application Laid-Open No. 2018-133575

### SUMMARY OF THE INVENTION

### Problems to be Solved by the Invention

One aspect of the present disclosure relates to a solid-state imaging element and an electronic device capable of suppressing a decrease in sensitivity even if a partition wall is provided between color filters for each pixel.

### Solutions to Problems

In order to solve the above-described problems, the present disclosure provides a solid-state imaging element including a plurality of pixels.

Each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.

The plurality of pixels may further include a light shielding film portion that shields a part of light incident on the photoelectric conversion unit, and
the inner region may be arranged according to a light transmission region of the light shielding film portion.

In the thickness direction of the color filter, an area ratio between the outer peripheral part and the inner region may vary according to a traveling direction of the incident light.

In the thickness direction of the color filter, the area of the inner region with respect to the outer peripheral part may be reduced according to the traveling direction of the incident light.

A light transmittance in the color filter may increase toward the optical axis of the first lens.

The color filter may include a plurality of color filters having different wavelength characteristics of light absorption, the plurality of color filters being formed at the outer peripheral part.

The plurality of pixels may include a plurality of stages of light shielding walls therebetween, and the inner region may be formed at a position corresponding to the inclination of the plurality of stages of light shielding walls.

The outer peripheral part may include a light shielding material.

The outer peripheral part may include a color filter having a higher light absorption rate than that of the inner region.

The plurality of pixels may further include a light shielding wall therebetween, and
a second lens between the light shielding walls.

The plurality of pixels may be arranged in a two-dimensional lattice pattern,
the plurality of pixels may include a color filter corresponding to any one of three different types of wavelength bands, and
the inner region of a color filter corresponding to at least two pixels of the plurality of pixels may include a color filter having a further different wavelength band from that of the color filter corresponding to the any one of the three different types of wavelength bands.

The three types of color filters may be arranged in a Bayer arrangement.

The three types of color filters may correspond to red, green, and blue as the wavelength bands, and the further different wavelength band may correspond to cyan.

The area of the inner region at a peripheral portion of the plurality of pixels arranged in the two-dimensional lattice pattern may be larger than the area of the inner region at a central portion of the plurality of pixels.

The at least two pixels may be phase difference detection pixels used to perform focus detection.

In order to solve the above-described problems, the present disclosure provides an electronic device including
a plurality of pixels.

Each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.

### BRIEF DESCRIPTION OF DRAWINGS

FIG. 1 is a schematic cross-sectional view of an electronic device according to a first embodiment.

FIG. 2 (a) is a schematic external view of the electronic device in FIG. 1, and FIG. 2(b) is a cross-sectional view taken along a line A-A in FIG. 2(a).

FIG. 3A is a block diagram illustrating a configuration example by a subpixel of the imaging unit.

FIG. 3B is a schematic plan view of a plurality of pixels in an imaging unit as viewed from a light incident side.

FIG. 4 is a view illustrating a cross-sectional structure taken along line AA in a case where a multi-stage lens of the pixel illustrated in FIG. 3B is used.

FIG. 5 is a plan view of a color filter of a phase difference detection pixel.

FIG. 6 is a diagram illustrating wavelength characteristics of color filters of red (R), green (G), and blue (B).

FIG. 7 is a diagram illustrating an arrangement example of color filters.

FIG. 8 is a diagram illustrating a phase difference detection pixel paired with the phase difference detection pixel illustrated in FIG. 4.

FIG. 9 is a diagram illustrating the outputs of pixels having right openings and the outputs of pixels having left openings for one column.

FIG. 10A is a diagram illustrating the combination of the red (R) filter and the cyan filter.

FIG. 10B is a diagram illustrating the combination of the green (G) filter and the cyan filter.

FIG. 10C is a diagram illustrating the combination of a light shielding film and the cyan filter.

FIG. 11 is a diagram illustrating a configuration example of an outer peripheral part in a color filter according to a second embodiment.

FIG. 12 is a diagram illustrating a configuration example of a first outer peripheral part and a second outer peripheral part in the color filter.

FIG. 13 is a view illustrating a configuration example of a tapered outer peripheral part.

FIG. 14 is a diagram illustrating an example where a tapered outer peripheral part is formed in an imaging pixel.

FIG. 15 is a diagram illustrating a configuration example of an outer peripheral part according to a modification of the second embodiment.

FIG. 16 is a diagram illustrating a configuration example of an outer peripheral part in a comparative example.

FIG. 17 is a diagram illustrating an example where a positional relationship between an outer peripheral part and an inner region varies according to a position in an imaging unit.

FIG. 18 is a diagram illustrating a configuration example of pixel pixels in a cross section taken along line BB.

FIG. 19 is a diagram illustrating an example where the size of the inner region varies according to the position in the imaging unit.

FIG. 20 is a schematic diagram illustrating an example where the orientation and shape of the inner region vary according to the position in the imaging unit.

FIG. 21A is a diagram illustrating a shape example of the inner region at the right end portion or the left end portion of the imaging unit.

FIG. 21B is a diagram illustrating a shape example of the inner region at the upper end portion or the lower end portion of the imaging unit.

### MODE FOR CARRYING OUT THE INVENTION

Hereinafter, an embodiment of an electronic device will be described with reference to the drawings. Although principal components of the electronic device are mainly described hereinafter, the electronic device may have components and functions that are not illustrated or described. The following description does not exclude components and functions that are not illustrated or described.

### First Embodiment

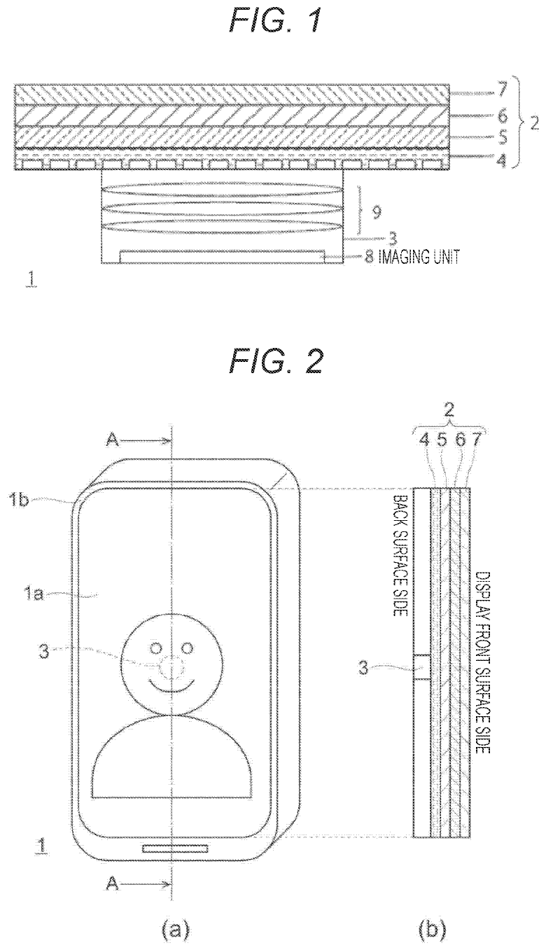

FIG. 1 is a schematic cross-sectional view of an electronic device 1 according to a first embodiment. The electronic device 1 in FIG. 1 is any electronic device having both a display function and an image capturing function, such as a smartphone, a mobile phone, a tablet, a PC, or a single-lens reflex. The electronic device 1 is provided with a camera module 3 on the back side of a display surface of a display unit 2. Therefore, the camera module 3 performs image capturing through the display unit 2.

FIG. 2(a) is a schematic external view of the electronic device 1 in FIG. 1, and FIG. 2(b) is a cross-sectional view taken along line A-A of FIG. 2(a). In an example in FIG. 2(a), a display screen 1a extends nearly the outer shape size of the electronic device 1, and the width of a bezel 1b around the display screen 1a is set to several millimeters or smaller. In general, a front camera is often mounted on the bezel 1b, but in FIG. 2(a), as indicated by a broken line, the camera module 3 serving as the front camera is arranged on the back surface side of a substantially central portion of the display screen 1a. Providing the front camera on the back surface side of the display screen 1a in this manner eliminates the need to arrange the front camera on the bezel 1b, thereby being capable of reducing the width of the bezel 1b.

Note that, in FIG. 2(a), the camera module 3 is arranged on the back surface side of the substantially central portion of the display screen 1a, but in this embodiment, it is sufficient that this is arranged on the back surface side of the display screen 1a, and the camera module 3 may be arranged on the back surface side near a peripheral edge of the display screen 1a, for example. In this manner, the camera module 3 in this embodiment is arranged in any position on the back surface side overlapping the display screen 1a.

As illustrated in FIG. 1, the display unit 2 is a structure in which a display panel 4, a touch panel 5, a circularly polarizing plate 6, and a cover glass 7 are layered in this order. The display panel 4 may be, for example, an organic light emitting device (OLED) unit, a liquid crystal display unit, a microLED, or the display unit 2 based on other display principles. The display panel 4 such as the OLED unit includes a plurality of layers. The display panel 4 is often provided with a member having a low transmittance, such as a color filter layer. A through hole may be formed in the member having a low transmittance in the display panel 4 according to a place in which the camera module 3 is arranged. If subject light having passed through the through hole is made incident on the camera module 3, the image quality of an image captured by the camera module 3 can be improved.

The circularly polarizing plate 6 is provided to reduce glare and enhance the visibility of the display screen 1a even in a bright environment. A touch sensor is incorporated in the touch panel 5. There are various types of touch sensors such as a capacitance type and a resistance film type, but any type may be used. Furthermore, the touch panel 5 and the display panel 4 may be integrated with each other. The cover glass 7 is provided to protect the display panel 4 and the like.

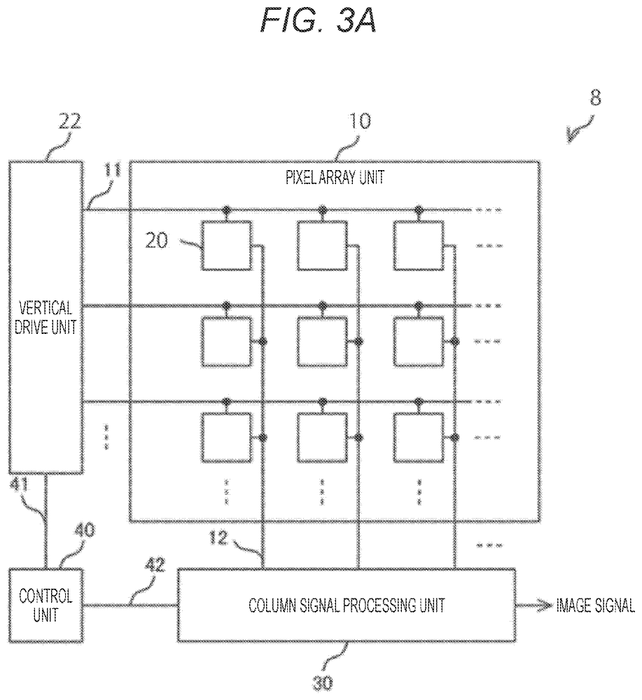

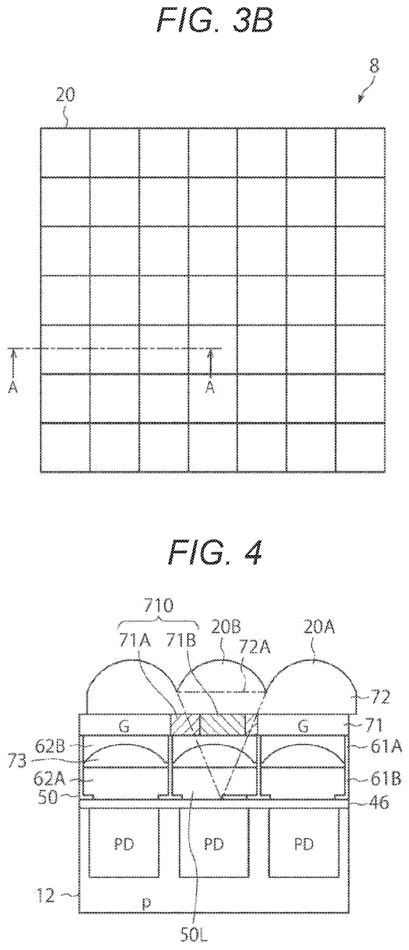

A case where a pixel 20 of an imaging unit 8 includes a multistage lens will be described. FIG. 3A is a block diagram illustrating a configuration example of the imaging unit 8. As illustrated in FIG. 3A, the imaging unit 8 is provided with a pixel array unit 10, a vertical drive unit 22, a column signal processing unit 30, and a control unit 40.

The pixel array unit 10 includes a plurality of pixels 20. That is, the plurality of pixels 20 is arranged in a two-dimensional lattice pattern. The pixel 20 generates an image signal according to applied light. The pixel 20 includes a photoelectric conversion unit that generates a charge according to the applied light. Furthermore, the pixel 20 further includes a pixel circuit. The pixel circuit generates an image signal based on the charge generated by the photoelectric conversion unit. Generation of the image signal is controlled by a control signal generated by the vertical drive unit 22 described later. In the pixel array unit 10, signal lines 11 and 12 are arranged in an XY matrix pattern. The signal line 11 is a signal line that transmits a control signal of the pixel circuit in the pixel 20, is arranged for each row of the pixel array unit 10, and is commonly wired to the pixels 20 arranged in each row. The signal line 12 is a signal line that transmits the image signal generated by the pixel circuit of the pixel 20, is arranged for each column of the pixel array unit 10, and is commonly wired to the pixels 20 arranged in each column. The photoelectric conversion unit and the pixel circuit are formed in a semiconductor substrate.

The vertical drive unit 22 generates the control signal of the pixel circuit of the pixel 20. The vertical drive unit 22 transmits the generated control signal to the pixel 20 via the signal line 11 in the drawing.

The column signal processing unit 30 processes the image signal generated by the pixel 20. The column signal processing unit 30 processes the image signal transmitted from the pixel 20 via the signal line 12 in the drawing. The processing by the column signal processing unit 30 corresponds to, for example, analog-digital conversion to convert an analog image signal generated by the pixel 20 into a digital image signal. The image signal processed by the column signal processing unit 30 is output as the image signal of the imaging element 1. The control unit 40 controls the entire imaging unit 8. The control unit 40 generates the control signal that controls the vertical drive unit 22 and the column signal processing unit 30 to control the pixel (imaging element) 20. The control signal generated by the control unit 40 is transmitted to the vertical drive unit 22 and the column signal processing unit 30 by signal lines 41 and 42, respectively.

FIG. 3B is a schematic plan view of an array structure in which the plurality of pixels 20 of the imaging unit 8 is viewed from a light entrance side. As illustrated in FIG. 3B, the imaging unit 8 includes the plurality of pixels 20. The plurality of pixels 20 is provided in an array along a first direction and a second direction intersecting the first direction. Note that the arrangement of the pixels is illustrated as an example, and the pixels are not necessarily provided in a rectangular shape or along the first direction and the second direction.

FIG. 4 is a diagram illustrating a cross-sectional structure of pixels 20A and 20B along a line AA in the present embodiment in FIG. 3B in a case where the pixels 20A and 20B have multistage lenses. The pixel 20A is an imaging pixel, and the pixel 20B is a phase difference detection pixel for performing focus detection.

As illustrated in FIG. 4, in the imaging unit 8, an n-type semiconductor region is formed in, for example, a p-type semiconductor region of a semiconductor substrate 12 for each of the pixels 20A and 20B, whereby a photoelectric conversion element PD is formed for each pixel. On the front surface side (lower side in the drawing) of the semiconductor substrate 12, a multilayer wiring layer including a transistor for performing reading of charges accumulated in the photoelectric conversion element PD, and the like and an interlayer insulating film is formed.

An insulating layer 46 having a negative fixed charge is formed at an interface on the back surface side (upper side in the drawing) of the semiconductor substrate 12. The insulating layer 46 includes a plurality of layers having different refractive indexes, for example, two layers of a hafnium oxide (HfO2) film and a tantalum oxide (Ta2O5) film.

A silicon oxide film is formed on the upper surface of the insulating layer 46, and a light shielding film portion 50 formed with an opening is formed on the silicon oxide film. The light shielding film portion 50 only needs to include a material that shields light, and preferably includes a film of metal, for example, aluminum (Al), tungsten (W), or copper (Cu) as a material having a high light shielding property and capable of being accurately processed by microfabrication, for example, etching. In the light shielding film portion 50 of the phase difference detection pixel 20B, a left opening 50L is formed as a transmission region.

On the light shielding film portion 50 and the insulating layer 46, a plurality of stages of layers of a first light shielding wall 61A and a flattening film 62 having a high light transmittance is formed. More specifically, the first light shielding wall 61A is formed in a part of a region on the light shielding film portion 50, and a first flattening film 62A is formed between the first light shielding walls 61A. Moreover, a second light shielding wall 61B and a second flattening film 62B are formed on the first light shielding wall 61A and the first flattening film 62A, respectively. Note that the light shielding wall herein may include a material of metal, for example, tungsten (W), titanium (Ti), aluminum (Al), or copper (Cu), or an alloy thereof, or a multi-layer film of these metals. Alternatively, this may include an organic light shielding material such as carbon black. Alternatively, a transparent inorganic film having a structure in which crosstalk is suppressed by a total reflection phenomenon due to a difference in refractive index may also be used, and for example, a shape in which an uppermost portion is closed as an air gap structure may also be used.

On the upper surfaces of the second light shielding wall 61B and the second flattening film 62B, for example, color filters 71 are formed for each pixel. As arrangement of the color filters 71, respective color filters of red (R), green (G), and blue (B) are arranged by, for example, a Bayer arrangement, but they may be arranged by other arrangement methods. Moreover, the color arrangement of the color filters 71 is not limited to red (R), green (G), and blue (B) (red, green, blue). Furthermore, some of the pixels do not necessarily include the color filters 71.

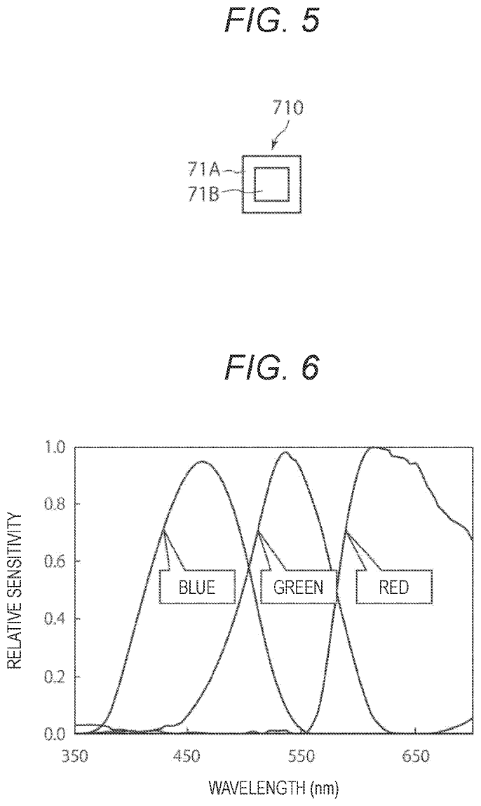

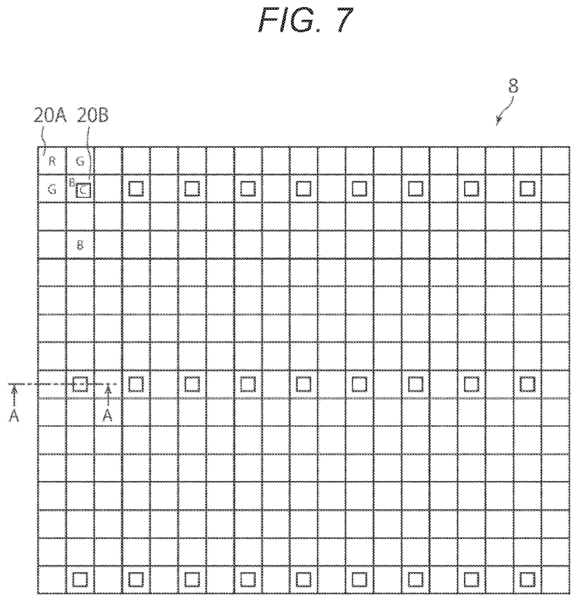

FIG. 5 is a plan view of a color filter 710 of the phase difference detection pixel 20B. As illustrated in FIG. 5, for example, an outer peripheral part 71A includes a blue (B) filter, and an inner region 71B includes a cyan (C) filter. Note that details of an arrangement example in the color filter 71 will be described later with reference to FIG. 7.

FIG. 6 is a diagram illustrating wavelength characteristics of the color filters 71 of red (R), green (G), and blue (B). The horizontal axis represents wavelength, and the vertical axis represents relative sensitivity. As illustrated in FIG. 6, the red (R), green (G), and blue (B) filters mainly transmit light in the red, green, and blue wavelength bands, respectively. That is, blue (B) has a higher absorption rate of red light and green light than that of the cyan filter (C). Therefore, the blue (B) filter suppresses the light incident on the phase difference detection pixel 20B from leaking to the surrounding imaging pixels 20A. This prevents the light incident on the phase difference detection pixel 20B from crossing the color filter of the phase difference detection pixel 20B and entering the color filter of the imaging pixel 20A. As described above, crosstalk (color mixture) due to the light incident on the photoelectric conversion element of the imaging pixel 20A is suppressed by the outer peripheral part 71A.

Again, as illustrated in FIG. 4, an on-chip lens 72 is formed on the color filter 71 for each pixel. The on-chip lens 72 may include an organic material such as styrene resin, acrylic resin, styrene-acrylic copolymer resin, or siloxane resin, for example. The styrene resin has a refractive index of about 1.6, and the acrylic resin has a refractive index of about 1.5. The styrene-acrylic copolymer resin has a refractive index of about 1.5 to 1.6, and the siloxane resin has a refractive index of about 1.45.

An inner lens 73 includes, for example, an inorganic material such as SiN or SiON. The inner lens 73 is formed on the formed first stage of light shielding wall layer (the first light shielding wall 61A and the first flattening film 62A).

As illustrated in FIG. 4, the inner region 71B is arranged according to a light condensing region 72A to which the incident light is condensed by the on-chip lens 72 in the color filter 71 of the phase difference detection pixel 20B. Furthermore, the light condensing region 72A of the incident light is formed such that the on-chip lens 72 condenses the light to the light transmission region (opening) of the light shielding film portion 50. That is, in other words, the inner region 71B is arranged according to the light transmission region of the light shielding film portion 50. With this configuration, absorption of the incident light by the outer peripheral part 71A is suppressed, and a decrease in the sensitivity of the photoelectric conversion element PD of the phase difference detection pixel 20B is suppressed.

FIG. 7 is a diagram illustrating an arrangement example of the color filters 71. The cross section taken along line AA in the drawing corresponds to the AA cross-sectional position illustrated in FIG. 3B. As illustrated in FIG. 7, respective colors of red (R), green (G), and blue (B) are arranged, for example, in a Bayer arrangement to form the imaging pixels 20A. In FIG. 7, the phase difference detection pixel 20B is formed in a pixel corresponding to blue (B), but the present invention is not limited thereto. For example, the phase difference detection pixels 20B may be formed in pixels corresponding to red (R) and green (G).

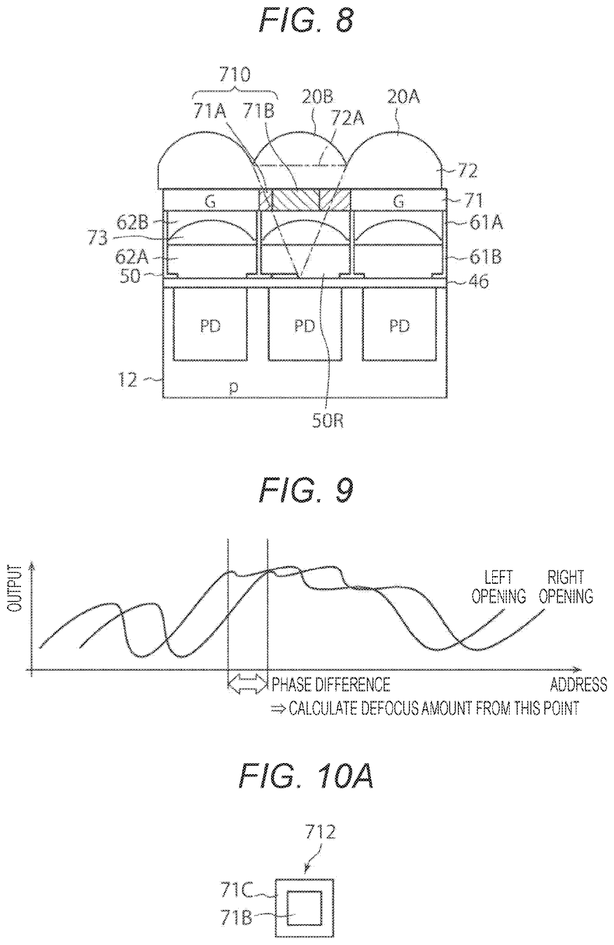

FIG. 8 is a diagram illustrating a phase difference detection pixel 20Bb paired with the phase difference detection pixel 20B illustrated in FIG. 4. In the light shielding film portion 50 of the phase difference detection pixel 20B, a right opening 50R is formed as a transmission region. The right opening 50R and the corresponding left opening 50L are bilaterally symmetrical with respect to the center line of the photoelectric conversion element PD, for example.

FIG. 9 is a diagram illustrating the outputs of pixels having the right openings 50L and the outputs of pixels having the left openings 50L for one column of the imaging unit 8. The vertical axis represents an output, and the horizontal axis represents the position (address) of the pixel. As illustrated in FIG. 51, an image shift occurs between pixel signals from the left openings and pixel signals from the right openings due to a difference in the formation position of the openings. A phase shift amount can be calculated from the shift of the image to calculate a defocus amount.

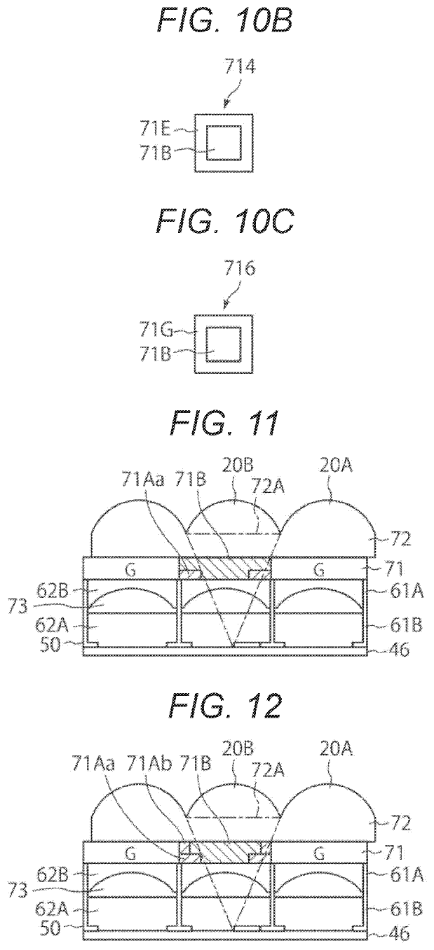

FIG. 10A is a diagram illustrating the combination of the red (R) filter and the cyan (C) filter. As illustrated in FIG. 10A, in a color filter 712, for example, an outer peripheral part 71C includes a red (R) filter, and an inner region 71B includes a cyan (C) filter. The phase difference detection pixel 20B may be configured such that the color filter 712 is replaced with the red (R) filter in FIG. 5. In this case, the outer peripheral part 71C can suppress leakage of the colors of green (G) and blue (B), and can suppress crosstalk with adjacent pixels.

FIG. 10B is a diagram illustrating the combination of the green (G) filter and the cyan (C) filter. As illustrated in FIG. 10B, in a color filter 714, for example, an outer peripheral part 71E includes a green (G) filter, and an inner region 71B includes a cyan (C) filter. The phase difference detection pixel 20B may be configured such that the color filter 714 is replaced with the green (G) filter in FIG. 5. In this case, the outer peripheral part 71E can suppress leakage of the colors of red (R) and blue (B), and can suppress crosstalk with adjacent pixels.

FIG. 10C is a diagram illustrating the combination of the light shielding film and the cyan (C) filter. As illustrated in FIG. 10C, in a color filter 716, for example, an outer peripheral part 71G includes a light shielding material or a color filter having a higher light absorption rate than that of an inner region 71B, and the inner region 71B includes a cyan (C) filter. The color filter having a higher light absorption rate is, for example, a black color filter. The phase difference detection pixel 20B may be configured such that the color filter 716 is replaced with the red (R) filter, the green (G) filter, and the blue (B) filter in FIG. 5. In this case, the outer peripheral part 71G can suppress leakage of all the colors, and can suppress crosstalk with adjacent pixels. Note that the color filters 710, 712, 714, and 716 may be used for the imaging pixel 20A. In this case, the outer peripheral parts 71A, 71C, 71E, and 71G having effects similar to that of a diaphragm can be formed on the color filters 71. In addition, the shape of the inner region 71B is not limited to a quadrangular shape. The shape of the inner region 71B may be a polygonal shape, a circular shape, an oval shape, or the like. Further, in the present embodiment, the inner region 71B includes the cyan (C) filter, but the present invention is not limited thereto. For example, the inner region 71B may include a white (W) filter.

As described above, according to the present embodiment, the wavelength characteristics of light absorption of the outer peripheral parts 71A, 71C, 71E, and 71G of the color filters 71 and the wavelength characteristics of light absorption of the inner region 71B of the color filter 71 are different from each other, and the inner region 71B is formed according to the light condensing region 72A of the incident light. With this configuration, even in a case where the phase difference detection pixels 20B or the imaging pixels 20 A are arranged in a binary manner and the position of the light condensing region 72A is different therebetween, absorption of the incident light by the outer peripheral parts 71A, 71C, 71E, and 71G is suppressed, and a decrease in the sensitivity of the photoelectric conversion element PD of the phase difference detection pixel 20B or the imaging pixel 20A is suppressed.

### Second Embodiment

An electronic device 1 according to a second embodiment is different from the electronic device 1 according to the first embodiment in that the configuration or shape of an outer peripheral part of a color filter 71 varies in the thickness direction of the color filter according to the traveling direction of incident light. Hereinafter, a difference from the electronic device 1 according to the first embodiment is described.

FIG. 11 is a diagram illustrating a configuration example of an outer peripheral part 71Aa in the color filter 71 of the electronic device 1 according to the second embodiment. As illustrated in FIG. 11, in the thickness direction of the color filter 71, the outer peripheral part 71Aa is not formed on a surface portion of the color filter 71, but is formed in the middle of the color filter 71. In the thickness direction of the color filter 71, the irradiation area of a light condensing region 72A narrows in the traveling direction of the incident light. Therefore, since the outer peripheral part 71Aa is not formed on the surface portion of the color filter 71, absorption of the incident light is further suppressed and the sensitivity of a photoelectric conversion element PD is further increased.

FIG. 12 is a diagram illustrating a configuration example of a first outer peripheral part 71Aa and a second outer peripheral part 71Ab in the color filter 71 of the electronic device 1 according to the second embodiment. As illustrated in FIG. 12, in the thickness direction of the color filter 71, the wall-shaped second outer peripheral part 71Ab is further formed at a boundary portion of the color filter 71, which is different from that of the color filter 71 of FIG. 12. The second outer peripheral part 71Ab suppresses light leakage to adjacent pixels, further suppresses absorption of the incident light, and further increases the sensitivity of the photoelectric conversion element PD. Note that the first outer peripheral part 71Aa and the second outer peripheral part 71Ab may be integrally formed, or the first outer peripheral part 71Aa and the second outer peripheral part 71Ab may be separately formed.

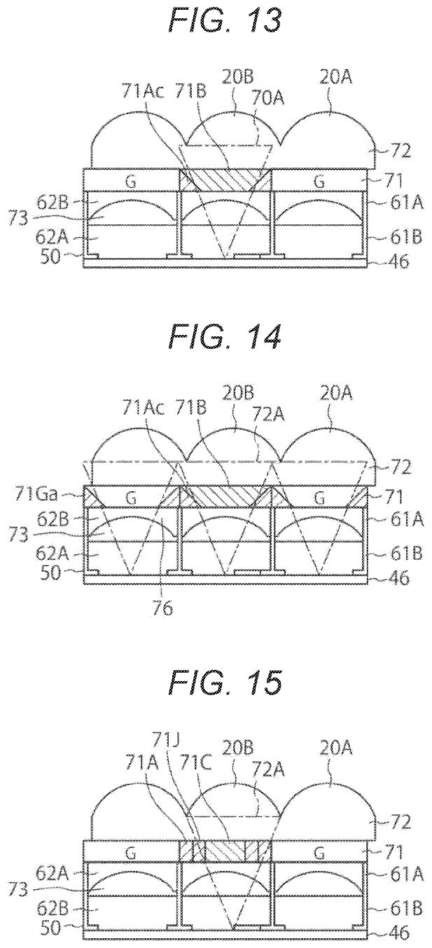

FIG. 13 is a diagram illustrating a configuration example of a tapered outer peripheral part 71Ac in the color filter 71. As illustrated in FIG. 13, in the thickness direction of the color filter 71, the outer peripheral part 71Ac is formed in a tapered shape according to the irradiation area of the light condensing region 72A. Light traveling in the light condensing region 72A is not inhibited, and light leakage to adjacent pixels is suppressed. Therefore, absorption of the incident light is further suppressed, and the sensitivity of the photoelectric conversion element PD is further increased.

As described above, the area of the inner region 71B with respect to the outer peripheral parts 71Aa, 71Ab, and 71Ac is reduced in the thickness direction of the color filter 71 according to the traveling direction of the incident light, so that the outer peripheral parts 71Aa, 71Ab, and 71Ac that do not inhibit the light traveling in the light condensing region 72A can be formed and a decrease in the sensitivity of the photoelectric conversion element PD can be suppressed.

FIG. 14 is a diagram illustrating an example where a tapered outer peripheral part 71Ga is formed in an imaging pixel 20A. As illustrated in FIG. 14, in the thickness direction of the color filter 71, the outer peripheral part 71Ga is formed in a tapered shape according to the irradiation area of the light condensing region 72A. Also in the imaging pixel 20A, light traveling in the light condensing region 72A is not inhibited, and light leakage to adjacent pixels is suppressed. Therefore, absorption of the incident light can be further suppressed, and a decrease in the sensitivity of the photoelectric conversion element PD can be further suppressed. Furthermore, the shape of the outer peripheral part 71Ga is adjusted so that the outer peripheral part 71Ga can function as a diaphragm of an on-chip lens 72.

As described above, according to the present embodiment, in the thickness direction of the color filter 71, the area ratio between the outer peripheral parts 71Aa, 71Ab, and 71Ac and the inner region 71B varies according to the traveling direction of the incident light. With this configuration, the outer peripheral parts 71Aa, 71Ab, and 71Ac that do not inhibit the light traveling in the light condensing region 72A can be formed, and a decrease in the sensitivity of the photoelectric conversion element PD can be further suppressed.

(Modification of Second Embodiment)

FIG. 15 is a diagram illustrating a configuration example of outer peripheral parts 71A and 71J according to a modification of the second embodiment. As illustrated in FIG. 15, in the color filter 71, the outer peripheral part 71J is further formed inside the outer peripheral part 71A. The light absorption rate of the outer peripheral part 71J is higher than that of the inner region 71B and lower than that of the outer peripheral part 71A. As described above, a plurality of color filters having different wavelength characteristics of light absorption is formed at the outer peripheral parts. With this configuration, the light transmittance of the color filter 71 can be increased toward the optical axis of the on-chip lens 72. Thus, light traveling in the light condensing region 72A is not inhibited, and light leakage to adjacent pixels is suppressed. Therefore, absorption of the incident light can be further suppressed, and a decrease in the sensitivity of the photoelectric conversion element PD can be further suppressed.

### Third Embodiment

An electronic device 1 according to a third embodiment is different from the electronic device 1 according to the first embodiment in that any one of the shape and position of an inner region 71B in a color filter 71 varies according to a light condensing state of an optical system 9 (see FIG. 1). Hereinafter, a difference from the electronic device 1 according to the first embodiment is described.

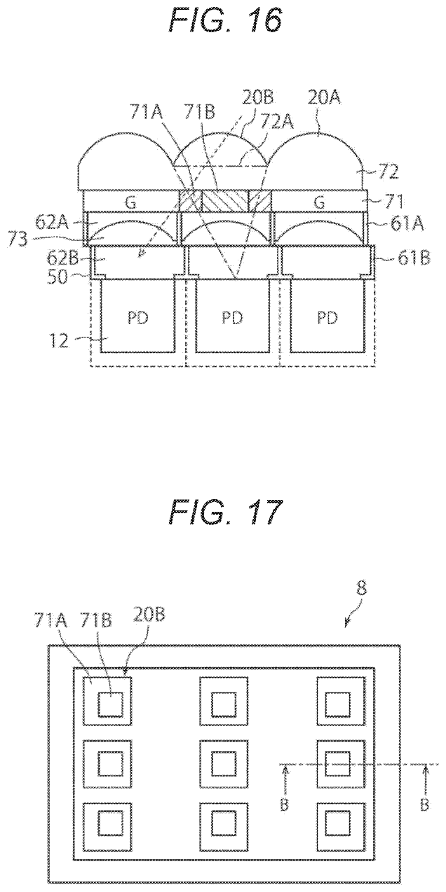

FIG. 16 is a diagram illustrating a configuration example of an outer peripheral part 71A in a comparative example. FIG. 16 illustrates, as the comparative example, an example where the width of the outer peripheral part 71A is the same on the left and right sides and the upper and lower sides of the pixel. As illustrated in FIG. 16, in a case where pixels 20A and 20B are arranged at an end portion of an imaging unit 8 (see FIG. 1), the positions of an on-chip lens 72 and a photoelectric conversion element PD are shifted by so-called pupil correction. However, it is difficult to reduce, only by the pupil correction, an area where light traveling in a light condensing region 72A is inhibited by the left outer peripheral part 71A in the figure. For this reason, in the present embodiment, in addition to the pupil correction, one of the shape or the position of the inner region 71B varies according to the light condensing state of the optical system 9 (see FIG. 1).

FIG. 17 is a schematic diagram illustrating an example where a positional relationship between the outer peripheral part 71A and the inner region 71B varies according to the position in an imaging unit 8. As illustrated in FIG. 17, the position of the inner region 71B is changed according to the position in the imaging unit 8. More specifically, as the pixels 20A and 20B are positioned closer to the left end portion of the imaging unit 8, the position of the inner region 71B is more eccentric, conversely, to the right side. Similarly, as the pixels 20A and 20B are positioned closer to the right end portion of the imaging unit 8, the position of the inner region 71B is more eccentric, conversely, to the left side. Similarly, as the pixels 20A and 20B are positioned closer to the upper end portion of the imaging unit 8, the position of the inner region 71B is more eccentric, conversely, to the lower side. Similarly, as the pixels 20A and 20B are positioned closer to the upper end portion of the imaging unit 8, the position of the inner region 71B is more eccentric, conversely, to the lower side.

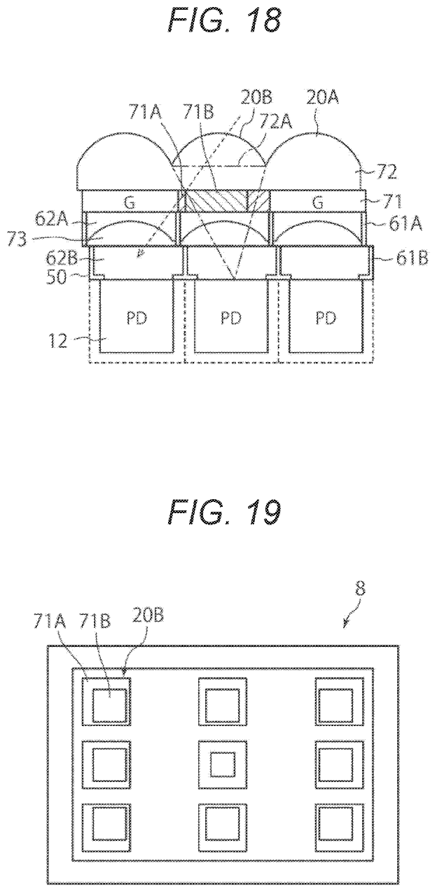

FIG. 18 is a diagram illustrating a configuration example of the pixel pixels 20A and 20B in a cross section taken along line BB. As illustrated in FIG. 18, in a case where the pixels 20A and 20B are arranged at the right end portion of the imaging unit 8, the position of the inner region 71B is eccentric to the left side so that the outer peripheral part 71A that does not inhibit light traveling in the light condensing region 72A can be formed and a decrease in the sensitivity of the photoelectric conversion element PD can be further suppressed. As described above, the plurality of pixels 20A and 20B includes a plurality of stages of light shielding walls 61A and 61B therebetween, and the inner region 71B is formed at the position corresponding to the inclination of the plurality of stages of light shielding walls 61A and 61B. That is, the position of the inner region 71B is eccentric in addition to the pupil correction so that the area where light traveling in the light condensing region 72A is inhibited can be further reduced as compared to the comparative example.

FIG. 19 is a schematic diagram illustrating an example where the positional relationship between the outer peripheral part 71A and the inner region 71B and the size of the inner region 71B vary according to the position in the imaging unit 8. As illustrated in FIG. 19, the position and size of the inner region 71B are changed according to the position in the imaging unit 8. More specifically, as the pixels 20A and 20B are positioned closer to the left end portion of the imaging unit 8, the position of the inner region 71B is more eccentric, conversely, to the right side and the size of the inner region 71B is larger. Similarly, as the pixels 20A and 20B are positioned closer to the right end portion of the imaging unit 8, the position of the inner region 71B is more eccentric, conversely, to the left side and the size of the inner region 71B is larger. Similarly, as the pixels 20A and 20B are positioned closer to the upper end portion of the imaging unit 8, the position of the inner region 71B is more eccentric, conversely, to the lower side and the size of the inner region 71B is larger. Similarly, as the pixels 20A and 20B are positioned closer to the upper end portion of the imaging unit 8, the position of the inner region 71B is more eccentric, conversely, to the lower side and the size of the inner region 71B is larger. In this manner, in addition to the eccentricity similar to that in FIG. 17, the size of the inner region 71B is made larger toward the end portion. The change area of the light condensing region 72A is also larger toward the end portion. With this configuration, even if the light condensing region 72A changes, interference with light traveling in the light condensing region 72A can be prevented.

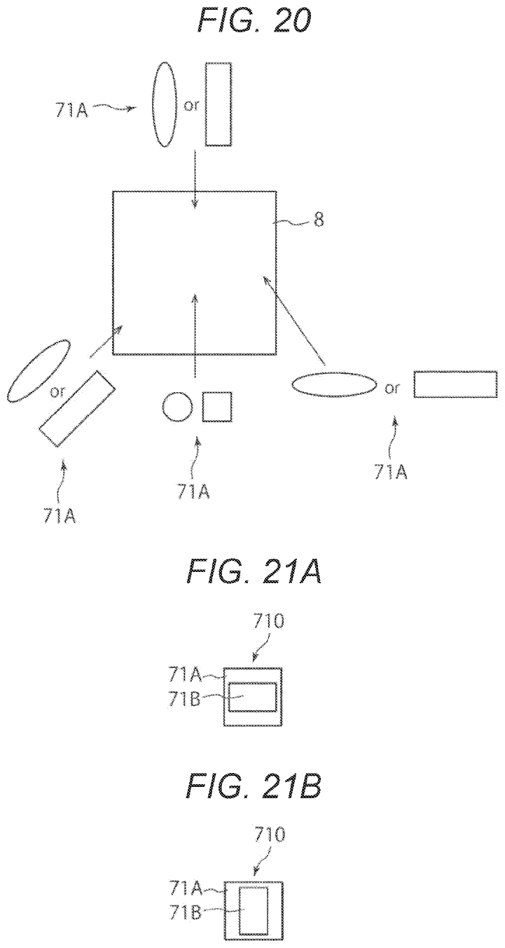

FIG. 20 is a schematic diagram illustrating an example where the orientation and shape of the inner region 71B vary according to the position in the imaging unit 8. FIG. 21A is a diagram illustrating a shape example of the inner region 71B at the right end portion or the left end portion of the imaging unit 8. FIG. 21B is a diagram illustrating a shape example of the inner region 71B at the upper end portion or the lower end portion of the imaging unit 8.

As illustrated in FIGS. 20, 21A, and 21B, the inner region 71B has a square or circular shape at the center of the imaging unit 8, and becomes a quadrangular shape having a longer side or an oval shape having a longer major axis toward the end portion. In addition, the orientation of the quadrangular shape or the oval shape is set so as to face the optical axis direction of the optical system 9 (see FIG. 1). With this configuration, the outer peripheral part 71A that does not inhibit the light traveling in the light condensing region 72A can be formed, and a decrease in the sensitivity of the photoelectric conversion element PD can be further suppressed.

As described above, according to the present embodiment, at least any one of the position, area, or shape of the inner region 71B is changed according to the position of the plurality of pixels 20A and 20B arranged in a two-dimensional lattice pattern. With this configuration, the outer peripheral part 71A that does not inhibit the light traveling in the light condensing region 72A can be formed regardless of the positions of the pixels 20A and 20B, and a decrease in the sensitivity of the photoelectric conversion element PD can be further suppressed.

Note that the present technology can have the following configurations.

(1) A solid-state imaging element including
a plurality of pixels,
in which each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.

(2) The solid-state imaging element according to (1),
in which the plurality of pixels further includes a light shielding film portion that shields a part of light incident on the photoelectric conversion unit, and
the inner region is arranged according to a light transmission region of the light shielding film portion.

(3) The solid-state imaging element according to (1), in which in the thickness direction of the color filter, an area ratio between the outer peripheral part and the inner region varies according to the traveling direction of the incident light.

(4) The solid-state imaging element according to (3), in which in the thickness direction of the color filter, an area of the inner region with respect to the outer peripheral part is reduced according to the traveling direction of the incident light.

(5) The solid-state imaging element according to (1), in which a light transmittance in the color filter increases toward the optical axis of the first lens.

(6) The solid-state imaging element according to (5), in which the color filter includes a plurality of color filters having different wavelength characteristics of light absorption, the plurality of color filters being formed at the outer peripheral part.

(7) The solid-state imaging element according to (1), in which the plurality of pixels includes a plurality of stages of light shielding walls therebetween, and the inner region is formed at a position corresponding to the inclination of the plurality of stages of light shielding walls.

(8) The solid-state imaging element according to (1), in which the outer peripheral part includes a light shielding material.

(9) The solid-state imaging element according to (1), in which the outer peripheral part includes a color filter having a higher light absorption rate than that of the inner region.

(10) The solid-state imaging element according to (1),
in which the plurality of pixels further includes a light shielding wall therebetween, and
a second lens between the light shielding walls.

(11) The solid-state imaging element according to (1),
in which the plurality of pixels is arranged in a two-dimensional lattice pattern,
the plurality of pixels includes a color filter corresponding to any one of three different types of wavelength bands, and
the inner region of a color filter corresponding to at least two pixels of the plurality of pixels includes a color filter having a further different wavelength band from that of the color filter corresponding to the any one of the three different types of wavelength bands.

(12) The solid-state imaging element according to (11), in which the three types of color filters are arranged in a Bayer arrangement.

(13) The solid-state imaging element according to (11), in which the three types of color filters correspond to red, green, and blue as the wavelength bands, and the further different wavelength band corresponds to cyan.

(14) The solid-state imaging element according to (11), in which at least any one of the position, shape, or area of the inner region varies according to the position of the plurality of pixels arranged in the two-dimensional lattice pattern.

(15) The solid-state imaging element according to (14), in which the area of the inner region at the peripheral portion of the plurality of pixels arranged in the two-dimensional lattice pattern is larger than the area of the inner region at the central portion of the plurality of pixels.

(16) The solid-state imaging element according to (11), in which the at least two pixels are phase difference detection pixels used to perform focus detection.

(17) An electronic device including
a plurality of pixels arranged in a two-dimensional lattice pattern and having a light shielding wall therebetween,
in which each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Electronic device
20 Pixel
20A Imaging pixel
20Bb Phase difference detection pixel
61A, 61B Light shielding wall
71 Color filter
71A, 71Aa, 71Ab, 71Ac, 71C, 71E, 71G, 71Ga, 71J Outer peripheral part
71B Inner region
72 On-chip lens
73 Inner lens
710, 712, 714, 716 Color filter
PD Photoelectric conversion element

What is claimed is:

1. A solid-state imaging element comprising:
a plurality of pixels,
wherein each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.

2. The solid-state imaging element according to claim 1,
wherein the plurality of pixels further includes a light shielding film portion that shields a part of light incident on the photoelectric conversion unit, and
the inner region is arranged according to a light transmission region of the light shielding film portion.

3. The solid-state imaging element according to claim 1, wherein in a thickness direction of the color filter, an area ratio between the outer peripheral part and the inner region varies according to a traveling direction of the incident light.

4. The solid-state imaging element according to claim 3, wherein in the thickness direction of the color filter, an area of the inner region with respect to the outer peripheral part is reduced according to the traveling direction of the incident light.

5. The solid-state imaging element according to claim 1, wherein a light transmittance in the color filter increases toward an optical axis of the first lens.

6. The solid-state imaging element according to claim 5, wherein the color filter includes a plurality of color filters having different wavelength characteristics of light absorption, the plurality of color filters being formed at the outer peripheral part.

7. The solid-state imaging element according to claim 1, wherein the plurality of pixels includes a plurality of stages of light shielding walls therebetween, and the inner region is formed at a position corresponding to an inclination of the plurality of stages of light shielding walls.

8. The solid-state imaging element according to claim 1, wherein the outer peripheral part includes a light shielding material.

9. The solid-state imaging element according to claim 1, wherein the outer peripheral part includes a color filter having a higher light absorption rate than that of the inner region.

10. The solid-state imaging element according to claim 1,
wherein the plurality of pixels further includes a light shielding wall therebetween, and
a second lens between the light shielding walls.

11. The solid-state imaging element according to claim 1,
wherein the plurality of pixels is arranged in a two-dimensional lattice pattern,
the plurality of pixels includes a color filter corresponding to any one of three different types of wavelength bands, and
the inner region of a color filter corresponding to at least two pixels of the plurality of pixels includes a color filter having a further different wavelength band from that of the color filter corresponding to the any one of the three different types of wavelength bands.

12. The solid-state imaging element according to claim 11, wherein the three types of color filters are arranged in a Bayer arrangement.

13. The solid-state imaging element according to claim 11, wherein the three types of color filters correspond to red, green, and blue as the wavelength bands, and the further different wavelength band corresponds to cyan.

14. The solid-state imaging element according to claim 11, wherein at least any one of a position, a shape, or an area of the inner region varies according to a position of the plurality of pixels arranged in the two-dimensional lattice pattern.

15. The solid-state imaging element according to claim 14, wherein the area of the inner region at a peripheral portion of the plurality of pixels arranged in the two-dimensional lattice pattern is larger than the area of the inner region at a central portion of the plurality of pixels.

16. The solid-state imaging element according to claim 11, wherein the at least two pixels are phase difference detection pixels used to perform focus detection.

17. An electronic device, comprising:
a plurality of pixels arranged in a two-dimensional lattice pattern and having a light shielding wall therebetween,
wherein each of the plurality of pixels includes
a first lens that condenses incident light,
a color filter that absorbs light having transmitted through the first lens and having a specific wavelength, the color filter having different wavelength characteristics of light absorption between an outer peripheral part and an inner region of the outer peripheral part, and
a photoelectric conversion unit that photoelectrically converts the incident light having transmitted through the color filter, and
the inner region is formed according to a light condensing region of the incident light in the color filter.
